(19) United States
(12) Patent Application Publication
(10) Pub. No.: US 2003/0205768 A1
(43) Pub. Date: Nov. 6, 2003

(54) Active matrix current source controlled gray level tunable FED

(76) Inventors: Yu-Wu Wang, Taichung (TW); Chun-Tao Lee, Hsinchu (TW); Cheng-Chung Lee, Hsinchu (TW)

Correspondence Address: BIRCH STEWART KOLASCH & BIRCH, PO BOX 747, FALLS CHURCH, VA, 22040-0747, US

(21) Appl. No.: 10/412,275

(22) Filed: Apr. 14, 2003

(30) Foreign Application Priority Data
May 3, 2002 (TW) 91109214

(51) Int. Cl. H01L 21/00; H01L 29/76; H01L 31/00

(52) U.S. Cl. 257/379; 438/20; 438/149; 257/444

(57) ABSTRACT

An active matrix current source controlled gray level tunable FED. The inventive FED uses active devices to convert a voltage-controlled signal into an output current and a capacitor to record and hold the voltage-controlled signal, thereby producing a low control voltage and active current source driving FED. As such, adjustment and maintenance of the gray level brightness of the FED is achieved because the brightness fixed by the active devices and the capacitor can obtain a high transient brightness when the FED operates in a lower voltage and brightness, thereby producing a high average brightness and avoiding an arc from high-voltage operation or poor vacuum.

### BACKGROUND OF THE INVENTION

1. Field of the Invention

The present invention relates to an active matrix current source controlled gray level tunable FED, which uses active devices to convert a voltage-controlled signal into an output current and a capacitor to record and hold the voltage-controlled signal, thereby producing a low control voltage and active current source driving FED. As such, adjustment and maintenance of the gray level brightness of the FED is achieved.

2. Description of Related Art

FIG. 1 is a schematic diagram of a typical diode FED. As shown in FIG. 1, the diode FED operates at a high voltage provided by its anode 11 to directly draw electrons out of an electron emitter 13, such as CNT, in a cathode 12 and hit it on an anode plate with phosphor powder (not shown) to illuminate the FED. With such a passive operation, a PWM technique is necessary to control the operating time provided by the anode to adjust the apparent gray level. Additionally, the electrons have to be emitted within a certain time to provide a high transient brightness to obtain the desired gray level in a frame time. However, this causes life cycle reduction and higher control voltage (anode voltage) requirement. FIG. 2 is a schematic diagram of a typical triode FED. As shown in FIG. 2, the triode FED operates at a high voltage provided by its anode 21, and however it, different from the diode FED, uses a gate 24 to control the high voltage in order to reduce the required voltage to draw electrons out of an electron emitter 23 in a cathode 22. Thus, the control voltage (anode voltage) can be lower. Currently, the positive voltage control mode used by the gate electrode has not the function of switching the FED and also needs the PWM to give the control signal to illuminate the anode 21 plate with phosphor power (not shown) so that the illuminated high brightness causes persistence of vision (normally, 1/12 to 1/16 second), thereby controlling the gray level of the FED. Also, this mode may shorten life cycle of the FED and reduce the FED reliability. FIG. 3 is a schematic diagram of a typical active controlled diode FED. In FIG. 3, the FED includes an active device 31 and a diode FED 32. The active device 31 can be a transistor with a gate 311, a source 312 and a drain 313. The emitter 323 of the diode FED 32 can be a CNT. As shown in FIG. 3, in the processes forming a transistor 31 by the semiconductor technique, CNTs are grown on the drain 313 using the CVD technique and further a cathode 322 is formed in the display 32. As such, the transistor 31 controls the current of the entire FED and the CNTs emit electrons so that in the prior art an active control is obtained without using the PWM and the unstable current in the CNTs is eliminated. FIG. 4 is a schematic diagram of an equivalent circuit of FIG. 3. As shown in FIG. 4, the active device (the gated transistor 31) is turned on/off by controlling the voltage Vg on the scan line 41 of the equivalent circuit so that the voltage Vd signal on the data line 42 enters the cathode 322 of the diode FED to control the electron beam on/off, so as to determine exciting of the phosphor powder to illuminate or not. Thus, the required gray level is obtained by controlling the on/off duration (i.e., light-emitting time). The structure has advantages of low control voltage and high anode voltage. However, the diode FED will turn off as soon as the active device is turned off by the scan line 41 so that the gray level data existing in the diode FED is unstable and it reduces the ability of controlling the gray level data.

### SUMMARY OF THE INVENTION

Accordingly, an object of the invention is to provide an active matrix current source controlled gray level tunable FED, which uses active devices to convert a voltage-controlled signal into an output current and a capacitor to record and hold the voltage-controlled signal, thereby producing a low control voltage and active current source driving FED. As such, adjustment and maintenance of the gray level brightness of the FED is achieved.

The invention is an active matrix current source controlled gray level tunable FED, which can record and hold the voltage-controlled signal to achieve the purpose of automatically controlling the desired gray level and brightness. The tunable FED includes two active devices and a capacitor. The capacitor has one end to the ground and the other end connected to the connection point of two active devices. The connection point is formed by connecting a drain of one active device to a gate of the other active device. Thus, a data line signal can control the other active device through the one active device to activate the FED and keep the other active device working through the capacitor when the one active device is turned off. As such, it can automatically control and adjust the FED gray level reliability.

### BRIEF DESCRIPTION OF THE DRAWINGS

FIG. 1 is a schematic diagram of a typical diode FED;

FIG. 2 is a schematic diagram of a typical triode FED;

FIG. 3 is a schematic diagram of a typical active controlled diode FED;

FIG. 4 is a schematic diagram of an equivalent circuit of FIG. 3;

FIG. 5 is a schematic diagram of an active matrix current source controlled gray level tunable FED in accordance with the invention;

FIG. 6 is a schematic diagram of an equivalent circuit of FIG. 5 in accordance with the invention;

FIG. 7 is a schematic diagram of another active matrix current source controlled gray level tunable FED in accordance with the invention; and

FIG. 8 is a schematic diagram of an application example in accordance with the invention.

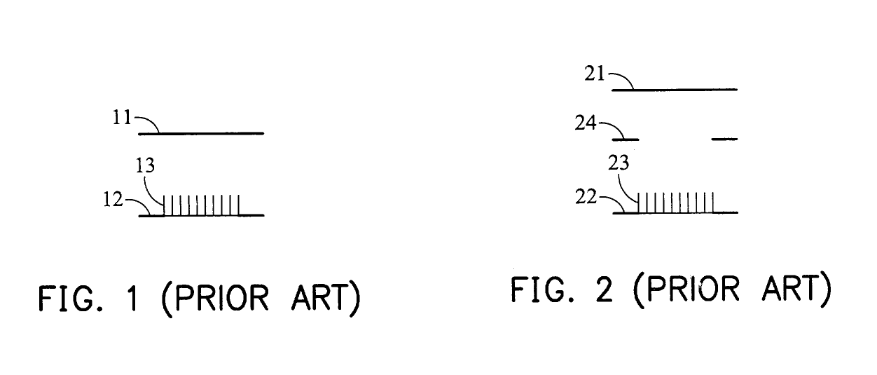

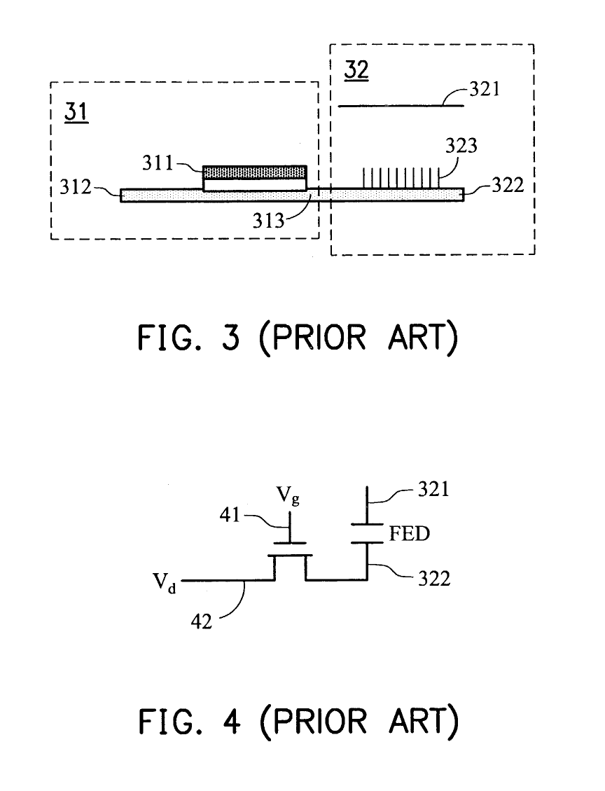

### DETAILED DESCRIPTION OF THE INVENTION

The following similar function elements are denoted by the same reference numerals.

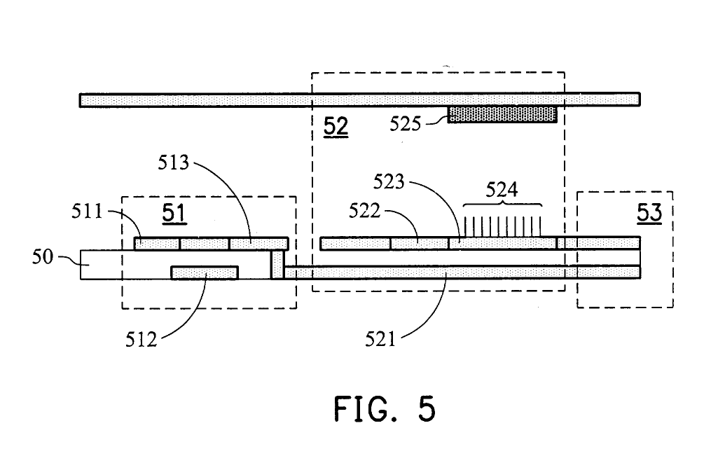

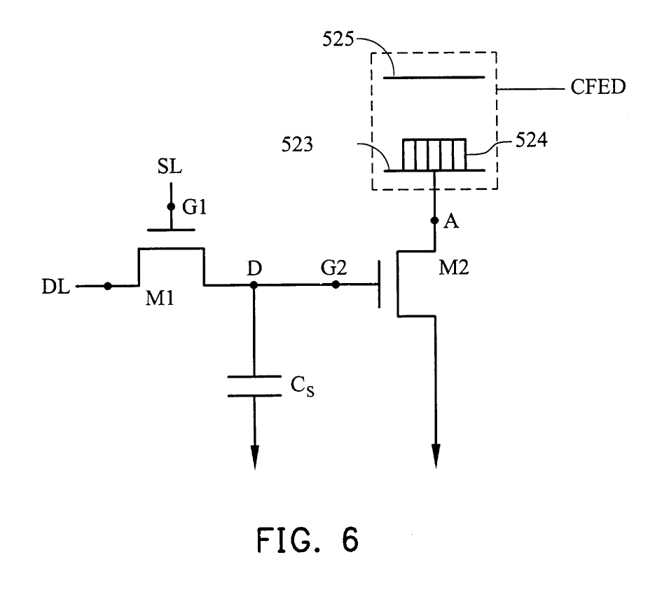

FIG. 5 is a schematic diagram of an active matrix current source controlled gray level tunable FED in accordance with the invention. In FIG. 5, the FED includes: a first active device 51, a region 52 having a second active device and a portion of FED, and a capacitor 53. As shown in FIG. 5, the first active device 51 has a source 511 connected to a data line, a gate 512 to control the first active device on/off and a drain 513 connected to a gate 521 of the second active device. The FED has a cathode 523 connected to a source 522 of the second active device, CNTs 524 grown on the cathode 523 and an anode 525. Such a structure can be produced by using any prior art process such as a thin film, a thick film, an IC or an above-combined processing on a substrate 50 to finish the active devices, i.e., portions of 51, 53, 521 and 522, and the subsequent CVD technique to finish the FED, i.e., portions of 523, 524 and 525, thereby completing the entire structure. The prior art thin film and IC processing generally includes cladding, photolithography and etching techniques. The prior art thick processing essentially includes screen printing and firing techniques. FIG. 6 is an equivalent circuit of FIG. 5 according to the invention. In FIG. 6, devices M1, M2 and Cs represent 51, 52 and 53 in FIG. 5. As shown in FIG. 6, the operation is that a data line DL signal is sent through the device M1's source S and drain D to the device M2's gate when a scan line SL signal turns on the device M1 by its gate G1. Thus, device M2 is turned on and the current through M2 causes the FET CFET connected to the drain A of M2 to emit electron beam from the CNTs 524. The electron beam excites phosphor powder coating on the surface of the anode plate 525 to illuminate the FED. The brightness of the FED is determined by the amplitude of the current. The amplitude of the current is determined by the DL signal. Therefore, adjustment of the DL input signal can control the gray level of the FED automatically. Additionally, the capacitor Cs, connected to the connection point of devices M1 (with its drain D) and M2 (with its gate G2), can record (charge) the input signal. When the SL signal inputs and turns off the device M1, the capacitor starts to discharge to the device M2 through its gate G2 and keep the device M2 on in stable brightness (i.e., hold on stable gray level). The device CFED can also be triode FED.

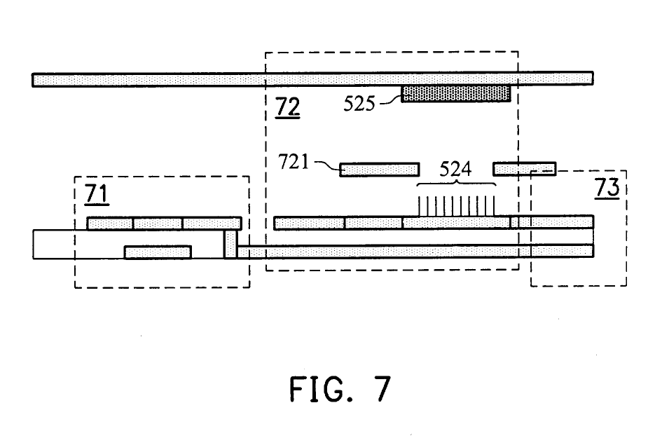

FIG. 7 is a schematic diagram of another active matrix current source controlled gray level tunable FED in accordance with the invention. In FIG. 7, an additional gate 721 is between the cathode 525 and the anode 523. As shown in FIG. 7, a constant voltage applies to the gate 721 to accelerate the electrons passing through the gate 721, thereby reducing the required current (in a unit of current density μA/cm²) drawing out of the electronic emitter 524 (i.e., CNTs) under the same brightness with the prior art diode FED. The remaining is identical to that in FIG. 5. Also, the gray level can be automatically controlled as well as shown in FIG. 5. The constant voltage can be determined by the distance between the gate 721 and the cathode 525 multiplied by the voltage density of 3-5V/μm. That is to say, the constant voltage will vary with the distance between the gate and the cathode. Normally, the constant voltage ranges from about few ten to few hundred volts.

As cited above, the FED control mode with the current signal of the data line can eliminate the great arc current from non-ideal vacuum due to the constant voltage (constant current source) and further increase the yield.

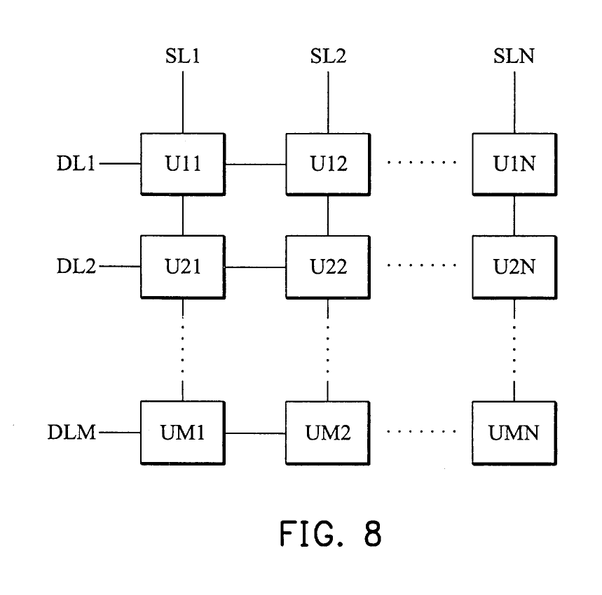

FIG. 8 is a schematic diagram of an application example in accordance with the invention. In FIG. 8, this application example is instructed by using the structure in FIG. 5 or 7 as a unit to be an M×N array. The M×N array has M×N elements with the notation U11-UMN and each element represents a pixel. The values of M and N are based on the display resolution, e.g., M=1024 and N=768 for XVGA, M=640 and N=480 for VGA, M=352 and N=288 for CIF and the like. As shown in FIG. 8, in first frame/scan number, the operation first activates all active devices (see FIG. 5 or 7) in the elements U11-UM1 of the first scan line SL1 to store data signals of the data lines DL1-DLM into the respective capacitors (see FIG. 5 or 7) of the elements U11-UM1. Thus, the pixels present different gray levels due to the different data signal voltage fed in the respective elements U11-UM1. The scan line SL1 is then deactivated, this causes the capacitor discharge to keep the gray levels in steady and hold on the data signals as same brightness as they input until other data signals come. As such, sequential activation of all scan lines SL1-SLN to complete a frame write-in and display operation. Due to the active devices and the capacitor, the repeating of the frame write-in and display operation for every frame can automatically control and adjust the gray level of the FED. The active matrix current source controlled gray level tunable FED is achieved.

Although the present invention has been described in its preferred embodiment, it is not intended to limit the invention to the precise embodiment disclosed herein. Those who are skilled in this technology can still make various alterations and modifications without departing from the scope and spirit of this invention. Therefore, the scope of the present invention shall be defined and protected by the following claims and their equivalents.

What is claimed is:

1. An active matrix current source controlled gray level tunable FED, comprising:
a first MOS device, having a first gate connected to an external scan line to control the first active device on/off, a source connected to an external data line to receive a gray level signal, and a drain;
a second MOS device, having a second gate connected to the drain of the first active device to receive the gray level signal, and a terminal connected to an FED to provide the FED the gray level signal; and
a capacitor, having one terminal connected to the second gate and the other terminal connected to the ground, thereby recording the gray level signal when the first active device turns on and discharging to keep the second active device on and hold on the gray level signal at the level of providing to the FED.

2. The active matrix current source controlled gray level tunable FED of claim 1, wherein the FED has a cathode with a CNT emitter to emit an electron beam and an anode to draw the electron beam out of the CNT emitter.

3. The active matrix current source controlled gray level tunable FED of claim 1, wherein the FED has a cathode with a CNT emitter to emit an electron beam, a gate to accelerate the electron beam and an anode to draw the electron beam out of the CNT emitter.

4. The active matrix current source controlled gray level tunable FED of claim 1, wherein the terminal connected to the FED is a source.

5. An active matrix current source controlled gray level tunable FED, comprising an active matrix formed of a plurality of tunable units, each tunable unit having:
a first MOS device, having a first gate connected to an external scan line to control the first active device on/off, a source connected to an external data line to receive a gray level signal, and a drain;
a second MOS device, having a second gate connected to the drain of the first active device to receive the gray level signal, and a terminal connected to an FED to provide the FED the gray level signal; and
a capacitor, having one terminal connected to the second gate and the other terminal connected to the ground, thereby recording the gray level signal when the first active device turns on and discharging to keep the second active device on and hold on the gray level signal at the level of providing to the FED.

6. The active matrix current source controlled gray level tunable FED of claim 1, wherein the FED has a cathode with a CNT emitter to emit an electron beam and an anode to draw the electron beam out of the CNT emitter.

7. The active matrix current source controlled gray level tunable FED of claim 1, wherein the FED has a cathode with a CNT emitter to emit an electron beam, a gate to accelerate the electron beam and an anode to draw the electron beam out of the CNT emitter.

8. The active matrix current source controlled gray level tunable FED of claim 1, wherein the terminal connected to the FED is a source.

9. A method of forming an active matrix current source controlled gray level tunable FED, comprising the steps:
forming a first and second MOS devices, wherein the first MOS device has a first gate connected to an external scan line to control the first active device on/off, a source connected to an external data line to receive a gray level signal, and a drain, and the second MOS device has a second gate connected to the drain of the first active device to receive the gray level signal, a source connected to the ground and a drain;
forming a capacitor having one terminal connected to the second gate and the other terminal connected to the ground; and
forming an FED connected to the drain of the second MOS device.

10. The method of claim 9, wherein the first and second MOS devices are formed using a thin film fabrication process.

11. The method of claim 9, wherein first and second MOS devices are formed using a thick film fabrication process.

12. The method of claim 9, wherein the first and second MOS devices are formed using an IC fabrication process.

13. The method of claim 9, wherein the first and second MOS devices are formed using a combination of thin film, thick film and IC fabrication processes.

14. The method of claim 9, wherein the capacitor is formed using a thin film fabrication process.

15. The method of claim 9, wherein the capacitor is formed using a thick film fabrication process.

16. The method of claim 9, wherein the capacitor is formed using an IC fabrication process.

17. The method of claim 9, wherein the capacitor is formed using a combination of thin film, thick film and IC fabrication processes.

18. The method of claim 9, wherein the FED is formed using a thin film fabrication process.

19. The method of claim 9, wherein the FED is formed using a thick film fabrication process.

20. The method of claim 9, wherein the FED is formed using an IC fabrication process.

21. The method of claim 9, wherein the FED is formed using a combination of thin film, thick film and IC fabrication processes.

22. The method of claim 9, wherein the step of forming an FED comprises formation of a cathode with a CNT emitter and an anode to display the gray level signal converted from an electron beam emitted by the CNT emitter, according to a current's amplitude provided by the external data line.

23. The method of claim 9, wherein the step of forming an FED comprises formation of a cathode with a CNT emitter, a gate with a constant voltage and an anode to display the gray level signal converted from an electron beam, emitted by the CNT emitter and accelerated by the constant voltage, according to a current's amplitude provided by the external data line.
